(19) United States
(12) Patent Application Publication
(10) Pub. No.: US 2022/0179186 A1
(43) Pub. Date: Jun. 9, 2022

(54) MICRO 3D VISUALIZATION AND SHAPE RECONSTRUCTION COMPOSITIONS AND METHODS THEREOF

(71) Applicant: THE TEXAS A&M UNIVERSITY SYSTEM, College Station, TX (US)

(72) Inventor: Dugan UM, College Station, TX (US)

(21) Appl. No.: 17/540,684

(22) Filed: Dec. 2, 2021

Related U.S. Application Data
(60) Provisional application No. 63/121,416, filed on Dec. 4, 2020.

(51) Int. Cl. G02B 21/36; H04N 13/211; H04N 13/254; H04N 13/122; G06F 30/10

(52) U.S. Cl. CPC G02B 21/367; H04N 13/211; G06F 30/10; H04N 13/122; H04N 13/254

(57) ABSTRACT

The present disclosure provides a microscale three-dimensional modeling system comprising a lighting condition, a camera, a microscope, and a mobile photographic platform. Methods of utilizing the system are also included in the present disclosure, including a method of generating a three-dimensional surface model of an object as well as a method of generating a three-dimensional CAD model of an object.

### CROSS REFERENCE TO RELATED APPLICATIONS

This application claims the benefit under 35 USC § 119(e) of U.S. Provisional Application Ser. No. 63/121,416, filed on Dec. 4, 2020, the entire disclosure of which is incorporated herein by reference.

### BACKGROUND

Three-dimensional (3D) depth sensing and imaging technology provides scalable benefits in object recognition and identification. For instance, 3D depth imaging has enabled new levels of acquisition details in sensing not only by enhancing two-dimensional (2D) imaging but also providing extra domain information for various applications. Compared to 2D vision, 3D vision is easier for shape analysis, and more robust in object identification and classification due to the extra dimensional depth values.

However, current 3D technologies have multiple shortcomings and lack many desirable features. For example, blurriness of 3D imaging results in an inability of reconstruction a microscale object with concave surfaces, especially a concave shape vertical to the scanning plane. In addition, lengthy scanning time to process multiple layers at a time demerit the use of the confocal imaging system. Finally, the high price tag for the complex imaging system for precision scanning control also leads to the large barrier for many users in various applications.

Structure from Motion (“SfM”) is a photogrammetric range imaging technique to generate a three-dimensional surface via image stitching process. The SfM technology reconstructs a 3D model by using motion parallax, which is the foundation of depth generation by measuring amount of move of each feature as the camera moves. For instance, an object close to camera moves faster than an object far away from it as the camera moves side by side. The fundamental mechanism of 3D construction is similar to that of the stereo-vision, but photos next to each other forms a pair of stereo-vision, thus to enable 3D reconstruction.

Although the SfM technique has advantages, current methods are primarily limited to macroscale applications. In particular, a microscale SfM system has not been reported primarily due to problems with miniaturization of the techniques. Accordingly, the present disclosure provides microscale three-dimensional modeling systems utilizing SfM as well as methods of using the system to meet this need.

### SUMMARY

The systems and methods of the present disclosure provide several benefits compared to currently known techniques. Several different factors for development of the described systems and methods utilizing SfM technology were recognized by the inventor and addressed in the present disclosure. For example, development of SfM technology to be used on a microscale level had to solve the problem of the inability of surface texture changes, difficulties in ambient light control, and difficulties in capturing sequence generation. The concept of microscale SfM is shown in FIG. 1.

Structure from Motion (SfM) is a 3D reconstruction technique that estimates three-dimensional structures from two-dimensional images by searching for common features or an object from different images. Generally, SfM works on the assumption that a near object moves more than an object far away as the camera moves. Precision modeling with SfM requires specific capturing sequences and guidelines, including determination of several factors that influence the accuracy of a 3D model by SfM techniques on a microscale level.

First, types of cameras to use with the SfM system should be considered. Agisoft, one of the leading companies in SfM technique, recommends a high-resolution camera for 3D modeling processes that is difficult to accommodate in microscale applications. Therefore, in miniaturization of the described systems and methods, careful consideration of cameras were made by the inventor.

Second, if a data set was captured with a special type of lens such as a fisheye lens, then the lens factor needs to be calibrated. This concept provides an additional barrier for a microscale SfM techniques since photographs must be taken by the camera lens and also through the lens assembly of a microscope. Accordingly, in miniaturization of the described systems and methods, careful consideration of lenses were made by the inventor.

A further difficulty in microscale SfM techniques is the inability to provide surface texture control. In macroscale SfM techniques, the texture of an object is important. Generally speaking, a finely textured surface is preferable to a shiny surface due to the metashape distortion by inconsistent light reflectance. In the widely used Phong's illumination model, both diffusivity and specularity portions are included in light reflectance. Phong's illumination model and photometry theory proposed that the light intensity, I, is provided by the variables Co and C1, which are two coefficients (diffusivity and specularity) that express the reflectivity of the surface being sensed, Further, n is a power that models the specular reflection for each material and vectors μₛ, μₙ, μᵣ, and μᵥ are the light source, surface normal, reflected, and viewing vector, respectively (see FIG. 2).

In FIG. 2, θ stands for the angle between the reflected light and viewing angle. The vector uₙ is the normal to the object's surface at the point of interest, P, and d stands for the distance vectors (l) from each light source to the point, α is the angle between land the normal vector N. As expressed in the equation (1), diffusivity and specularity play an important role in light reflectance measure, of which the accuracy of the photographic 3D modeling will be calculated. Inconsistency in the scene from different locations or angles will disturb the modeling accuracy especially because of the feature matching process of the image stitching. The portion that could produce more inconsistency in the light intensity measure due mainly to the different angle or location is the specularity term in the equation. While the angle α maintains constant during the photographing process, the angle θ will change, disturbing the intensity due to the change in viewing angle. While diffusivity is less sensitive to the angle θ, specularity changes significantly. In order to minimize the specularity in the light reflectance, surface preprocessing may be required. For instance, if the target object is a car, spreading some talc powder (or anything similar) over the surface is required to change from glittering to dull surface. This mainly minimizes the effect of the specularity and maximizes the diffusivity to merit the field of view matching in multiple photographic images.

However, for microscale SfM technology, surface texture control is not feasible. In addition, ambient light control for microscale photography requires better control compared to macroscale, making the microscale SfM further difficult. As such, the inventor made careful consideration of these inadequacies in developing miniaturization of the described systems and methods.

Finally, another important factor in SfM technology is the capturing scenario in order to maximize the efficiency of the mathematical 3D photo stitching process. Generally, a 60% to 80% overlap between photos is necessary for the best modeling accuracy and thus a photography capturing sequence must be designed in a way that the stitching process is able to extract enough matching features from neighboring photos. This factor was also carefully considered by the inventor of the present disclosure.

Additional features of the present disclosure will become apparent to those skilled in the art upon consideration of illustrative embodiments exemplifying the best mode of carrying out the disclosure as presently perceived.

### BRIEF DESCRIPTIONS OF THE DRAWINGS

The detailed description particularly refers to the accompanying figures in which:

FIG. 1 shows the concept of Structure from Motion (SfM) technique.

FIG. 2 shows a diagram for Phong's illumination model and the associated formula.

FIG. 3 shows an experimental setup for microscale SfM comprising a gantry type microscope with a mobile platform underneath the microscope.

FIG. 4 shows a capturing sequence for an exemplary microscale SfM technique.

FIG. 5A shows absolute light conditions. FIG. 5B shows relative light conditions.

FIG. 6 shows the microscale gear comprising a length of 300 micrometers and a diameter of 70 micrometers as used for testing.

FIG. 7 shows that 5 of the 22 photos were identified with significant matching points using the absolute light condition.

FIG. 8A shows the reconstructed surface of the microscale gear object using the absolute light condition. FIG. 8B shows a sectional view of the object at the A-A distance shown in FIG. 8A.

FIGS. 9A and 9B show that all of the 22 photos were identified with significant matching points using the relative light condition.

FIG. 10A shows the reconstructed surface of the microscale gear object using the relative light condition. FIG. 10B shows a sectional view of the object at the A-A distance shown in FIG. 10A.

FIG. 11 shows a comparison of the number of recognized photos using the absolute light condition and the relative light condition.

FIG. 12A shows the micro-fluidic channel in comparison to a penny. FIG. 12B shows the original CAD design of the micro-fluidic channel.

FIG. 13A shows the first model created by the magnification factor of 30.

FIG. 13B shows that 17 point cloud data were captured from the model.

FIG. 14A shows the Euclidean distance of each point cloud data to the measured and plotted surface and FIG. 14B shows the surface fitting results.

FIG. 15 shows that 15 point cloud data were captured for surface flatness accuracy test.

FIG. 16A shows the collected data points by scatter 3D representation and FIG. 16B shows the surface fitting results.

FIGS. 17A-17B show a microscale 3D pyramid comprising a 450 μm² base and a 2,100 μm height (300 μm/step; 7 steps).

FIG. 18 shows construction of the microscale 3D pyramid using a magnitude factor of 70× zoom.

FIG. 19A shows a total of 12-point cloud data depicted in 3D scatter plot.

FIG. 19B shows the depth of the first two steps from the top were measured to be 287 μm and 295 μm, respectively, using the calibration factor (145.73).

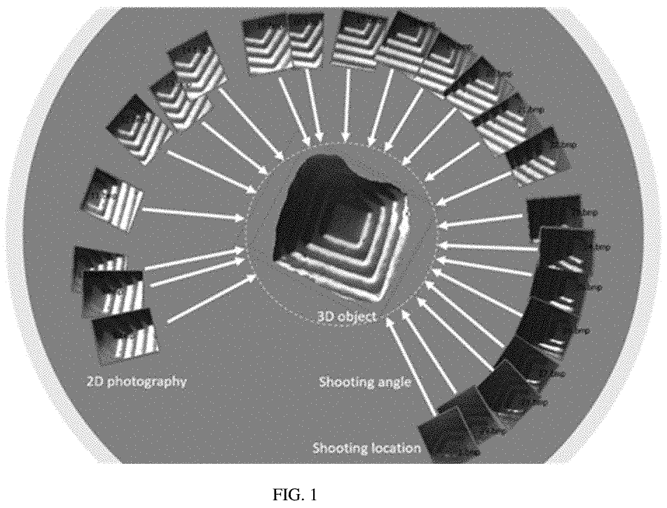

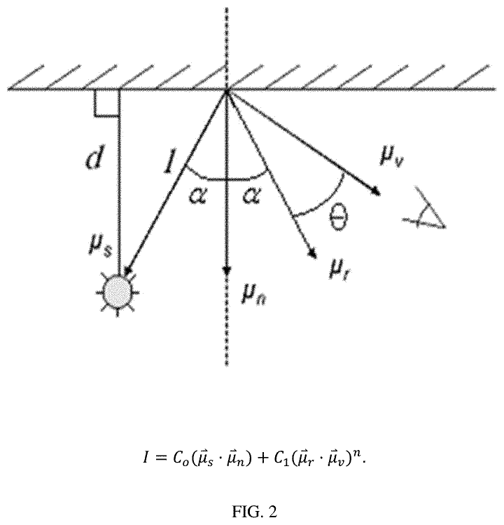

### DETAILED DESCRIPTION

In an illustrative aspect, a microscale three-dimensional modeling system is provided. The system comprises i) a lighting condition, ii) a camera, iii) a microscope, and iv) a mobile photographic platform.

In an embodiment, the lighting condition comprises absolute lightening, relative lightening, or a combination thereof. In an embodiment, the lighting condition comprises absolute lightening. In an embodiment, the lighting condition comprises relative lightening. In an embodiment, the lighting condition comprises a Gouraud lighting condition.

In an embodiment, the camera is a digital camera. In an embodiment, the camera comprises a fisheye lens. In an embodiment, the camera comprises a focal length that is greater than a depth of measurement.

In an embodiment, the camera comprises a lens comprising 50 mm focal length (35 mm film equivalent). In an embodiment, the camera comprises a lens comprising a focal length between 20 mm and 80 mm (35 mm film equivalent). In an embodiment, the camera comprises a zoom magnification power between 7× and 45×. In an embodiment, the camera comprises a widefield of view of 1.25 inches. In an embodiment, the camera comprises a working distance of 4 inches. In an embodiment, the camera is connected to the microscope.

In an embodiment, the microscope comprises a fixed lens. In an embodiment, the microscope comprises an adjustable depth of focus (DOF). In an embodiment, the microscope comprises a magnification power between 2× and 45×. In an embodiment, the microscope is a gantry-type microscope.

In an embodiment, the mobile photographic platform is configured under the microscope. In an embodiment, the mobile photographic platform comprises a piezo-electric mobile platform. In an embodiment, the mobile photographic platform comprises a rotational axis. In an embodiment, the mobile photographic platform comprises two degrees of freedom axes of rotational mobility. In an embodiment, the mobile photographic platform comprises a three Degree of Freedom X-Y-Z motion control system.

In an embodiment, the system further comprises a three-dimensional (3D) photography software. In an embodiment, the 3D photography software is a Surface from Motion (SfM)-based software. Software configured to provide SfM capabilities is known to the person of ordinary skill in the art and can be utilized with the system.

In an embodiment, the system further comprises a computer aided design (CAD) component. Components configured to provide CAD capabilities, such as CAD software, are known to the person of ordinary skill in the art and can be utilized with the system.

In an embodiment, the system is configured for surface modeling of a microscale object. In an embodiment, the microscale object is between 1 μm and 1000 μm in size. In an embodiment, the microscale object is between 100 μm and 1000 μm in size. In an embodiment, the microscale object is between 500 μm and 1000 μm in size.

It is contemplated that objects on a microscale can be observed according to the present disclosure. In an embodiment, the system is configured for surface modeling of a micro part assembly automation. In an embodiment, the system is configured for surface modeling of a biomedical device. In an embodiment, the system is configured for surface modeling of a biomedical device fabrication. In an embodiment, the system is configured for surface modeling of a biological specimen. In an embodiment, the system is configured for surface modeling of a microchemical specimen. In an embodiment, the system is configured for surface modeling of a physical specimen.

In an illustrative aspect, method of generating a three-dimensional surface model of an object is provided. The method comprises the step of using a microscale three-dimensional modeling system to provide the three dimensional surface model of the object a microscale three-dimensional modeling system. The microscale three-dimensional modeling system of any of the above embodiments can be utilized with the method of generating a three-dimensional surface model of an object.

In an embodiment, the method comprises a 3D photo stitching process. In an embodiment, the 3D photo stitching process comprises an overlap between photos between 60% and 80%. In an embodiment, the method comprises obtaining one or more photos of the object at a 45° angle around the vertical axis of the object.

In an embodiment, the object is between 1 μm and 1000 μm in size. In an embodiment, the object is between 100 μm and 1000 μm in size. In an embodiment, the object is between 500 μm and 1000 μm in size.

In an embodiment, the object comprises a micro part assembly automation. In an embodiment, the object comprises a composition comprising one or more microchannels. In an embodiment, the object comprises a biomedical device. In an embodiment, the object comprises a biomedical device fabrication. In an embodiment, the object comprises a biological specimen. In an embodiment, the object comprises a microchemical specimen. In an embodiment, the object comprises a physical specimen.

In an illustrative aspect, method of generating a three-dimensional CAD model of an object is provided. The method comprises the step of using a microscale three-dimensional modeling system to provide a three dimensional surface model of the object, and further comprising performing a CAD operation to provide the three dimensional CAD model of the object. The micro scale three-dimensional modeling system of any of the above embodiments can be utilized with the method of generating a three-dimensional CAD model of an object.

In an embodiment, the CAD operation comprises dimensioning of the object. In an embodiment, the CAD operation comprises volume measuring of the object. In an embodiment, the CAD operation comprises surface texturing of the object.

In an embodiment, the method comprises a 3D photo stitching process. In an embodiment, the 3D photo stitching process comprises an overlap between photos between 60% and 80%. In an embodiment, the method comprises obtaining one or more photos of the object at a 45° angle around the vertical axis of the object.

In an embodiment, the object is between 1 μm and 1000 μm in size. In an embodiment, the object is between 100 μm and 1000 μm in size. In an embodiment, the object is between 500 μm and 1000 μm in size.

In an embodiment, the object comprises a micro part assembly automation. In an embodiment, the object comprises a composition comprising one or more microchannels. In an embodiment, the object comprises a biomedical device. In an embodiment, the object comprises a biomedical device fabrication. In an embodiment, the object comprises a biological specimen. In an embodiment, the object comprises a microchemical specimen. In an embodiment, the object comprises a physical specimen.

The following numbered embodiments are contemplated and are non-limiting:

1. A microscale three-dimensional modeling system comprising i) a lighting condition, ii) a camera, iii) a microscope, and iv) a mobile photographic platform.
2. The system of clause 1, any other suitable clause, or any combination of suitable clauses, wherein the lighting condition comprises absolute lightening, relative lightening, or a combination thereof.
3. The system of clause 1, any other suitable clause, or any combination of suitable clauses, wherein the lighting condition comprises absolute lightening.
4. The system of clause 1, any other suitable clause, or any combination of suitable clauses, wherein the lighting condition comprises relative lightening.
5. The system of clause 1, any other suitable clause, or any combination of suitable clauses, wherein the lighting condition comprises a Gouraud lighting condition.
6. The system of clause 1, any other suitable clause, or any combination of suitable clauses, wherein the camera is a digital camera.
7. The system of clause 1, any other suitable clause, or any combination of suitable clauses, wherein the camera comprises a fisheye lens.
8. The system of clause 1, any other suitable clause, or any combination of suitable clauses, wherein the camera comprises a focal length that is greater than a depth of measurement.
9. The system of clause 1, any other suitable clause, or any combination of suitable clauses, wherein the camera comprises a lens comprising 50 mm focal length (35 mm film equivalent).
10. The system of clause 1, any other suitable clause, or any combination of suitable clauses, wherein the camera comprises a lens comprising a focal length between 20 mm and 80 mm (35 mm film equivalent).
11. The system of clause 1, any other suitable clause, or any combination of suitable clauses, wherein the camera comprises a zoom magnification power between 7× and 45×.
12. The system of clause 1, any other suitable clause, or any combination of suitable clauses, wherein the camera comprises a widefield of view of 1.25 inches.
13. The system of clause 1, any other suitable clause, or any combination of suitable clauses, wherein the camera comprises a working distance of 4 inches.
14. The system of clause 1, any other suitable clause, or any combination of suitable clauses, wherein the camera is connected to the microscope.
15. The system of clause 1, any other suitable clause, or any combination of suitable clauses, wherein the microscope comprises a fixed lens.
16. The system of clause 1, any other suitable clause, or any combination of suitable clauses, wherein the microscope comprises an adjustable depth of focus (DOF).
17. The system of clause 1, any other suitable clause, or any combination of suitable clauses, wherein the microscope comprises a magnification power between 2× and 45×.
18. The system of clause 1, any other suitable clause, or any combination of suitable clauses, wherein the microscope is a gantry-type microscope.
19. The system of clause 1, any other suitable clause, or any combination of suitable clauses, wherein the mobile photographic platform is configured under the microscope.
20. The system of clause 1, any other suitable clause, or any combination of suitable clauses, wherein the mobile photographic platform comprises a piezo-electric mobile platform.
21. The system of clause 1, any other suitable clause, or any combination of suitable clauses, wherein the mobile photographic platform comprises a rotational axis.
22. The system of clause 1, any other suitable clause, or any combination of suitable clauses, wherein the mobile photographic platform comprises two degrees of freedom axes of rotational mobility.
23. The system of clause 1, any other suitable clause, or any combination of suitable clauses, wherein the mobile photographic platform comprises a three Degree of Freedom X-Y-Z motion control system.
24. The system of clause 1, any other suitable clause, or any combination of suitable clauses, wherein the system further comprises a three-dimensional (3D) photography software.
25. The system of clause 24, any other suitable clause, or any combination of suitable clauses, wherein the 3D photography software is a Surface from Motion (SfM)-based software.
26. The system of clause 1, any other suitable clause, or any combination of suitable clauses, wherein the system further comprises a computer aided design (CAD) component.
27. The system of clause 1, any other suitable clause, or any combination of suitable clauses, wherein the system is configured for surface modeling of a microscale object.
28. The system of clause 27, any other suitable clause, or any combination of suitable clauses, wherein the microscale object is between 1 μm and 1000 μm in size.
29. The system of clause 27, any other suitable clause, or any combination of suitable clauses, wherein the microscale object is between 100 μm and 1000 μm in size.
30. The system of clause 27, any other suitable clause, or any combination of suitable clauses, wherein the microscale object is between 500 μm and 1000 μm in size.
31. The system of clause 1, any other suitable clause, or any combination of suitable clauses, wherein the system is configured for surface modeling of a micro part assembly automation.
32. The system of clause 1, any other suitable clause, or any combination of suitable clauses, wherein the system is configured for surface modeling of a composition comprising one or more microchannels.
33. The system of clause 1, any other suitable clause, or any combination of suitable clauses, wherein the system is configured for surface modeling of a biomedical device.
34. The system of clause 1, any other suitable clause, or any combination of suitable clauses, wherein the system is configured for surface modeling of a biomedical device fabrication.
35. The system of clause 1, any other suitable clause, or any combination of suitable clauses, wherein the system is configured for surface modeling of a biological specimen.
36. The system of clause 1, any other suitable clause, or any combination of suitable clauses, wherein the system is configured for surface modeling of a microchemical specimen.
37. The system of clause 1, any other suitable clause, or any combination of suitable clauses, wherein the system is configured for surface modeling of a physical specimen.
38. A method of generating a three-dimensional surface model of an object, said method comprising the step of using the microscale three-dimensional modeling system comprising i) a lighting condition, ii) a camera, iii) a microscope, and iv) a mobile photographic platform to provide the three dimensional surface model of the object.
39. The method of clause 38, any other suitable clause, or any combination of suitable clauses, wherein the microscale three-dimensional modeling system is the system of any one of clauses 1-37.
40. The method of clause 38, any other suitable clause, or any combination of suitable clauses, wherein the method comprises a 3D photo stitching process.
41. The method of clause 40, any other suitable clause, or any combination of suitable clauses, wherein the 3D photo stitching process comprises an overlap between photos between 60% and 80%.
42. The method of clause 38, any other suitable clause, or any combination of suitable clauses, wherein the method comprises obtaining one or more photos of the object at a 45° angle around the vertical axis of the object.
43. The method of clause 38, any other suitable clause, or any combination of suitable clauses, wherein the object is between 1 μm and 1000 μm in size.
44. The method of clause 38, any other suitable clause, or any combination of suitable clauses, wherein the object is between 100 μm and 1000 μm in size.
45. The method of clause 38, any other suitable clause, or any combination of suitable clauses, wherein the object is between 500 μm and 1000 μm in size.
46. The method of clause 38, any other suitable clause, or any combination of suitable clauses, wherein the object comprises a micro part assembly automation.
47. The method of clause 38, any other suitable clause, or any combination of suitable clauses, wherein the object comprises a composition comprising one or more microchannels.
48. The method of clause 38, any other suitable clause, or any combination of suitable clauses, wherein the object comprises a biomedical device.
49. The method of clause 38, any other suitable clause, or any combination of suitable clauses, wherein the object comprises a biomedical device fabrication.
50. The method of clause 38, any other suitable clause, or any combination of suitable clauses, wherein the object comprises a biological specimen.
51. The method of clause 38, any other suitable clause, or any combination of suitable clauses, wherein the object comprises a microchemical specimen.
52. The method of clause 38, any other suitable clause, or any combination of suitable clauses, wherein the object comprises a physical specimen.
53. A method of generating a three-dimensional CAD model of an object, said method comprising the step of using the microscale three-dimensional modeling system comprising i) a lighting condition, ii) a camera, iii) a microscope, and iv) a mobile photographic platform to provide a three dimensional surface model of the object, and further comprising performing a CAD operation to provide the three dimensional CAD model of the object.
54. The method of clause 53, any other suitable clause, or any combination of suitable clauses, wherein the microscale three-dimensional modeling system is the system of any one of clauses 1-37.
55. The method of clause 53, any other suitable clause, or any combination of suitable clauses, wherein the CAD operation comprises dimensioning of the object.
56. The method of clause 53, any other suitable clause, or any combination of suitable clauses, wherein the CAD operation comprises volume measuring of the object.
57. The method of clause 53, any other suitable clause, or any combination of suitable clauses, wherein the CAD operation comprises surface texturing of the object.
58. The method of clause 53, any other suitable clause, or any combination of suitable clauses, wherein the method comprises a 3D photo stitching process.
59. The method of clause 58, any other suitable clause, or any combination of suitable clauses, wherein the 3D photo stitching process comprises an overlap between photos between 60% and 80%.
60. The method of clause 53, any other suitable clause, or any combination of suitable clauses, wherein the method comprises obtaining one or more photos of the object at a 45° angle around the vertical axis of the object.
61. The method of clause 53, any other suitable clause, or any combination of suitable clauses, wherein the object is between 1 μm and 1000 μm in size.
62. The method of clause 53, any other suitable clause, or any combination of suitable clauses, wherein the object is between 100 μm and 1000 μm in size.
63. The method of clause 53, any other suitable clause, or any combination of suitable clauses, wherein the object is between 500 μm and 1000 μm in size.
64. The method of clause 53, any other suitable clause, or any combination of suitable clauses, wherein the object comprises a micro part assembly automation.
65. The method of clause 53, any other suitable clause, or any combination of suitable clauses, wherein the object comprises a composition comprising one or more microchannels.
66. The method of clause 53, any other suitable clause, or any combination of suitable clauses, wherein the object comprises a biomedical device.
67. The method of clause 53, any other suitable clause, or any combination of suitable clauses, wherein the object comprises a biomedical device fabrication.
68. The method of clause 53, any other suitable clause, or any combination of suitable clauses, wherein the object comprises a biological specimen.
69. The method of clause 53, any other suitable clause, or any combination of suitable clauses, wherein the object comprises a microchemical specimen.
70. The method of clause 53, any other suitable clause, or any combination of suitable clauses, wherein the object comprises a physical specimen.

### EXAMPLES

### Example 1

### Photograph Capturing Sequence

An important consideration in taking photographs of an object are the overlap and degree orientation of the photography. For instance, the photographs can be captured with 60% to 80% overlap for to provide for a desirable digital stitching process with 45 degree around the rotational axis, pointing the viewing angle toward the center of rotation. The sequence should be repeated with changing angles at a different latitude for the overlap in upper and lower parts of the photos as well.

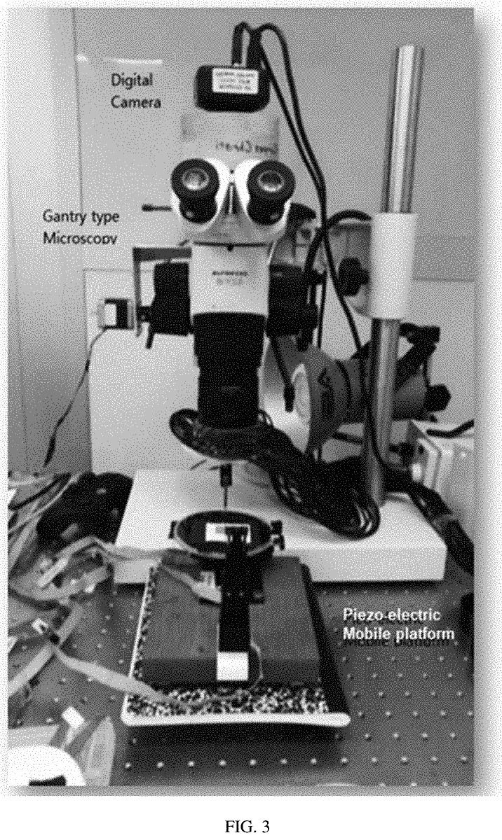

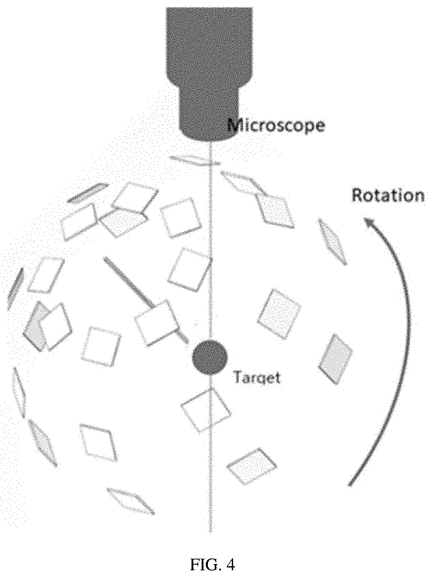

However, the proposed sequence cannot be easily achieved in a microscale technique since the microscope and the camera assembly cannot move to generate a macroscale scanning pattern. Thus, in order to generate an optimal scanning pattern in microscale, a gantry type microscope was assembled comprising a mobile platform underneath the microscope (see FIG. 3).

The microscope of the instant example can support an adjustable DOF (Depth of Focus) and has a magnification capability of up to 45 times (45×). The microscope and the photo-sequencing aperture were assembled on a vibration isolated table for precision photography in microscale. A piezo-electric mobile platform with a rotational axis was assembled and placed underneath the gantry-type microscope (0.02 mm position accuracy). A digital camera was attached on the microscope to enable digital shuttling so that no vibration was observed during the photography. The proposed configuration provides solid rigidity during the stationary photography and enables testing various capturing sequences for the microscale SfM.

In order to obtain a complete set of scanning photography of a microscale object for the SfM process, an exemplary capturing scenario is shown in Error! Reference source not found. The mobile platform underneath the microscope has two degrees of freedom axes of rotational mobility for varying latitude and longitude scanning. In addition, a three Degree of Freedom X-Y-Z motion control system enables precision focus of the microscale object for the microscope. The exemplary capturing sequence provides movement of the camera in order not to generate a blind-spot or to better understand concave shapes on the surface, thus to minimize visual occlusion.

In addition, compared to the confocal micro imaging technology (e.g., from Leica Microsystems), the scanning speed by the exemplary microscale SfM technique operates at much faster speeds. The scanning of an object with total of 30 photos by the exemplary microscale SfM technique takes only 30 seconds, while the point scanning by confocal imaging with a x-y-z table for multiple images takes up to 30 minutes or more. Without being held to any theory, it is believed that the fast scanning speed of the exemplary microscale SfM technique is because of the simple scanning procedure with two rotational axes of the scanning platform.

### Example 2

### Ambient Light Control

Unlike the macroscale SfM, ambient light control is an important factor for realizing a microscale SfM technique. Two different ambient light conditions can be taken into consideration: absolute light and relative light.

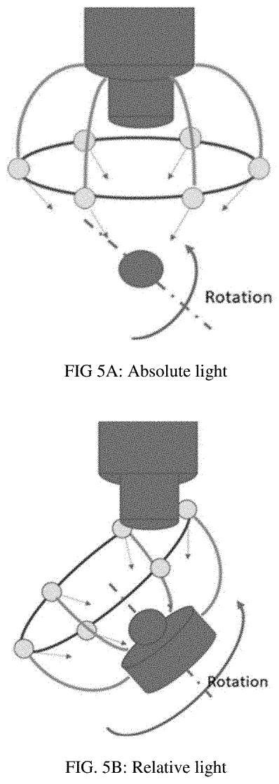

In absolute light condition, the light fixture is assembled on the microscope so that a fixed ambient light condition is achieved for the photo-sequencing process. In the relative light condition, the light fixture is installed on the mobile platform where the target sample is in place. The concept of the absolute and relative light conditions is shown in FIG. 5. It is contemplated that less disturbance in ambient light will be observed in the absolute light condition for the object, while a plain diffuse light condition for the camera may be achieved by the relative light condition.

Generally, it is believed that the enabling technique for surface reconstruction by multiple 2D images is the perspective projection. Given a set of m projective image spaces, there is a 3D subspace of the space of combined image coordinates called the joint images, P^{1, 2, . . . n}. These images in scaled coordinates compose a complete projective replica of the 3D world. A fundamental image in the joint image allows the reconstruction process through a matching constraint by which a set of image points, X^{1, 2, . . . m}, are classified to be the projection of a single world point, X. The matching process, then, produces a single compact geometric object using the antisymmetric 4 index joint Grassmannian tensor.

The essential mechanism of the projective reconstruction is matching point identification in multiple scaled images, or image points, X^{1, 2, . . . m}. A feature matching method can be used to form the fundamental matrix for the projective reconstruction. The same features in multiple images, therefore, should be easily identifiable by image transformation.

In addition to edge or point detection, an important aspect of the image transformation between photos are color-making attributes such as hue, intensity, luminance, brightness, chroma, and saturation, since the same feature in different photos may not be identified due to dissimilar chromaticity. While the absolute light condition provides a stable and consistent chromaticity with respect to the microscope, thus to the camera, the relative light condition is anticipated to provide consistency in chromaticity between pictures. Nevertheless, two different lightning conditions were examined to study the light effect on the microscale SfM technique.

### Example 3

### Evaluation of Absolute Light Condition and Relative Light Condition

In the instant example, the exemplary system included a gantry-type microscope to provide ample space below the microscopic lens in order to merit the flexibility of testing different light conditions and scanning sequences. A high definition digital camera was mounted on the microscope via an adapter for minimum disturbance in ambient light control. All experiments were performed in a light controlled cleanroom so that no external light influenced the photo-sequencing process other than the light fixture proposed for each configuration.

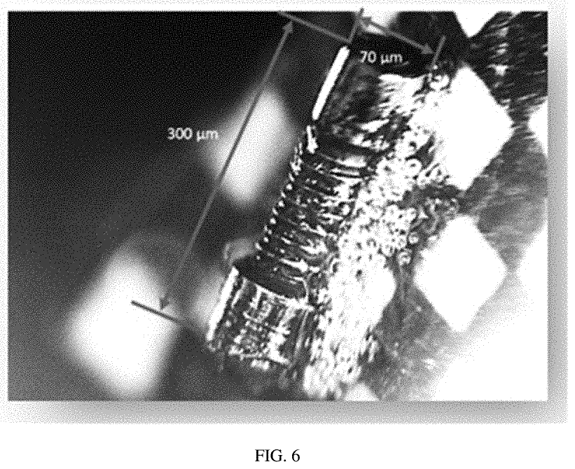

As shown in FIG. 6, the target object selected for testing was a microscale gear comprising a length of 300 micrometers and a diameter of 70 micrometers. This object is a common industrial element and was selected for a comparison of two different ambient light control settings (i.e. absolute light condition and relative light condition).

Absolute Light Condition: The number of identifiable photos is an important consideration for 3D modeling accuracy because a 3D model using SfM techniques is provided through stitching the photos identified during the image matching process. For a comparison between the absolute and the relative light conditions, the same number of photos (22) were taken for the projective reconstruction process.

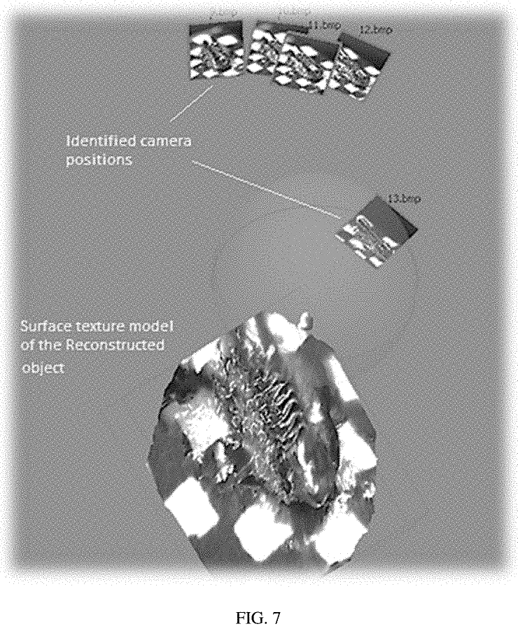

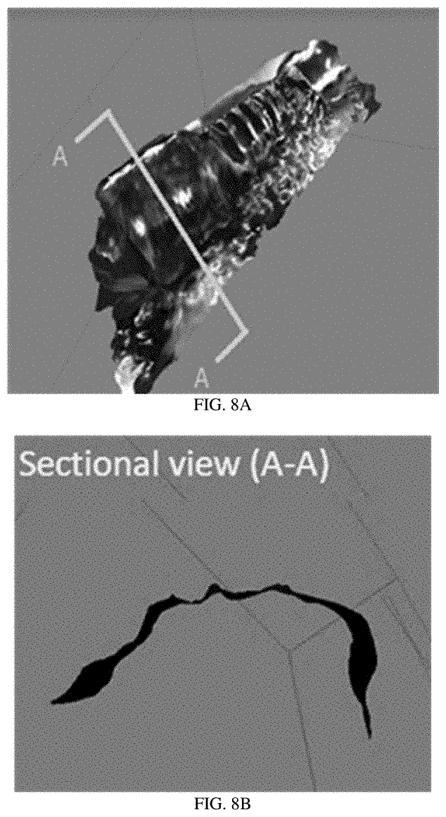

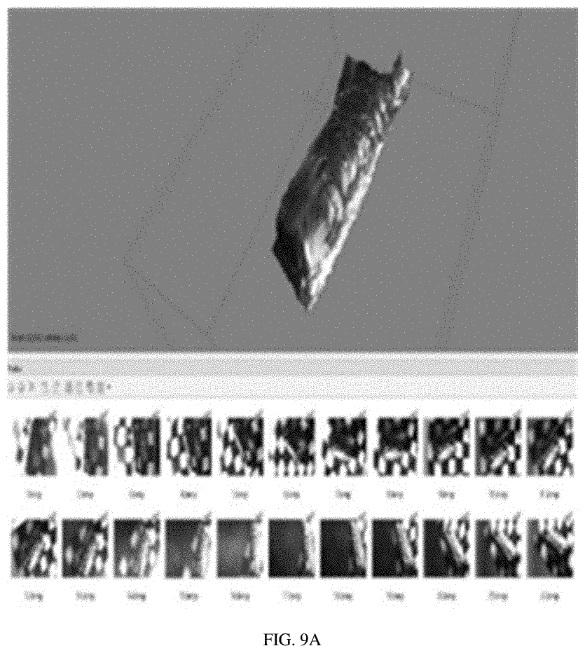

Using the absolute light condition, 5 of the 22 photos were identified with significant matching points in the first test (see FIG. 7). As a result, the reconstructed surface of the microscale gear object did not represent its original cylinder shape but, instead, was in a crushed cylinder form (see FIG. 8A). Further, FIG. 8B shows a sectional view of the object in FIG. 8A (i.e., at the A-A distance shown in FIG. 8A).

Upon examination of the photos taken in the absolute light condition, slightly different chromaticity between neighboring photos was evidenced for the same features. Different chromaticity of the same features may cause the variability in feature matching, thus leading to a distorted geometry of the original shape.

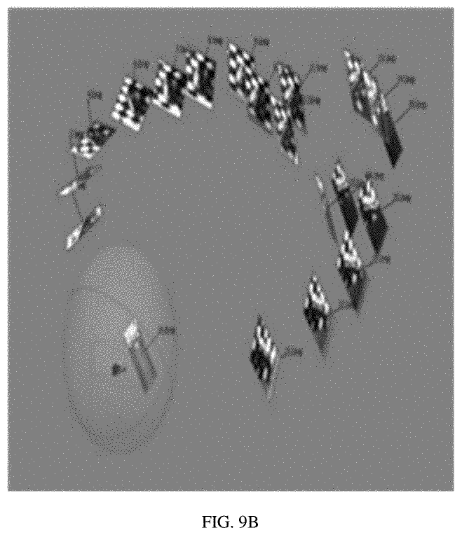

Relative Light Condition: In comparison, all of the 22 photos taken using relative light condition were identified due to the identical chromaticity of matching features in the first test (see FIGS. 9A and 9B). The localization errors of the camera viewpoints as shown in FIG. 8 may be due to the magnification adjustment during the photography process to obtain finer and crisp photos. The same technique is applied for the absolute light condition.

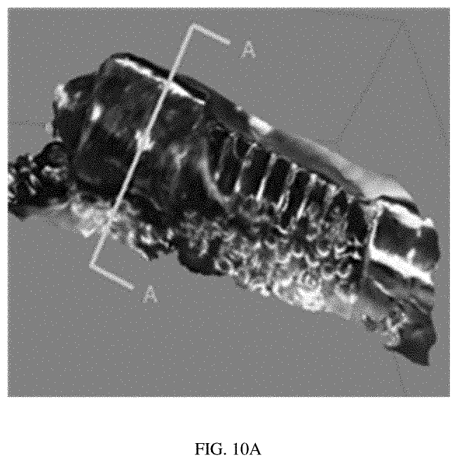

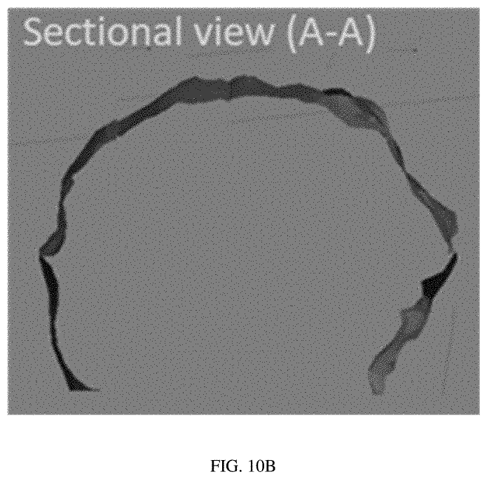

As a result, the completely reconstructed 3D model of the microscale gear object was observed to have an intact original shape (see FIG. 10A). The cross section of the gear (see FIG. 10B, which shows cross section at the A-A distance shown in FIG. 10A) demonstrates a complete circle of the microscale gear object shape with minimal distortion. Moreover, the reconstructed shape conforms to the original shape in scale ratio, thus virtual measurements of any part of the microscale object is made possible. For instance, the screw pitch was measured to be 9.49 micrometers by using the reconstructed 3D model.

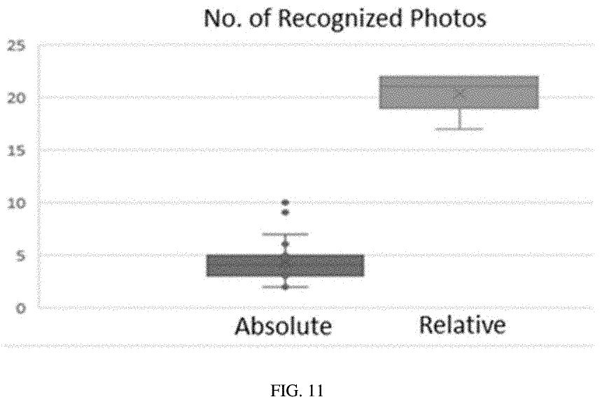

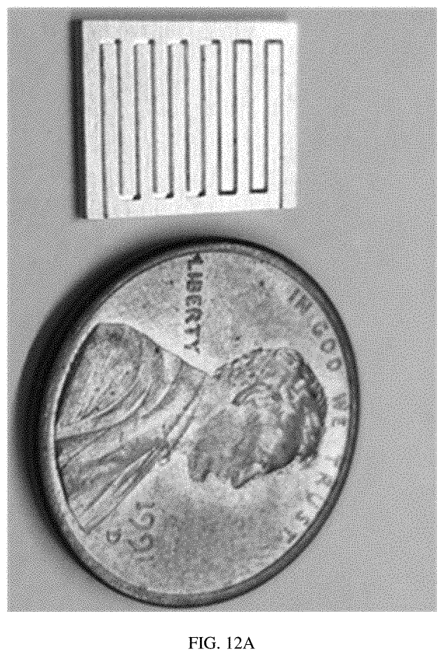

It is believed that the advantage using the relative light condition could be due to the fixed natural ambient light for the sample object, which can be similar to fixing the ambient light in macroscale with the camera rotating around an object. In comparison, the absolute lightning condition was akin to using a flashlight for each photograph in macroscale, thus disturbing the feature matching process. The discrepancy in the color attributes between potentially matching features can lead to an incomplete model using SfM techniques. Approximately 30 repetitions for testing each condition revealed that the relative light condition maintains an average of 20.3 photos recognized, in comparison to an average of 4.5 photos recognized using the absolute light condition (see FIG. 11).

### Example 4

### Modeling Accuracy

In order to evaluate the construction capabilities of the exemplary microscale SfM system, a micro-fluidic channel was analyzed to show the accuracy of 3D surface reconstruction. The micro-fluidic channel was manufactured by using a Micro-Milling Machine (363-S 3-Axis Horizontal Machining Center) powered by 50,000 RPM Electric Motor Driven High-Precision Bearing Spindle. The micro milling machine can carve a micro shape in the scale of 50 to 100 micrometer with 2-micron accuracy. The width of the micro-fluidic channel created for the 3D reconstruction test is 235 micrometers for Lab-On-Chip applications.

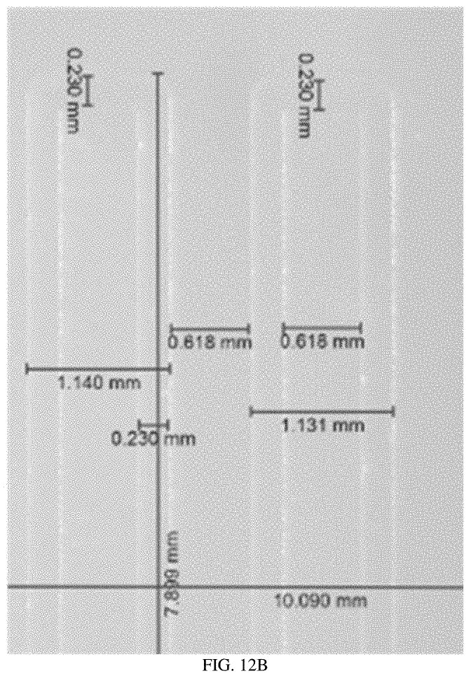

FIG. 12A shows the micro-fluidic channel in comparison to a penny. Each channel is spaced by 901 micrometers and the total micro-fluidic channel is bit smaller than the size of a penny. The original CAD design of the micro-fluidic channel is illustrated in FIG. 12B.

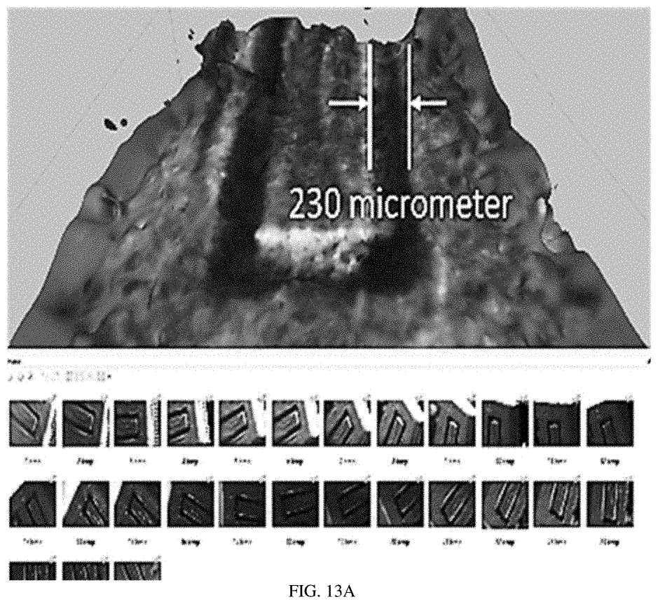

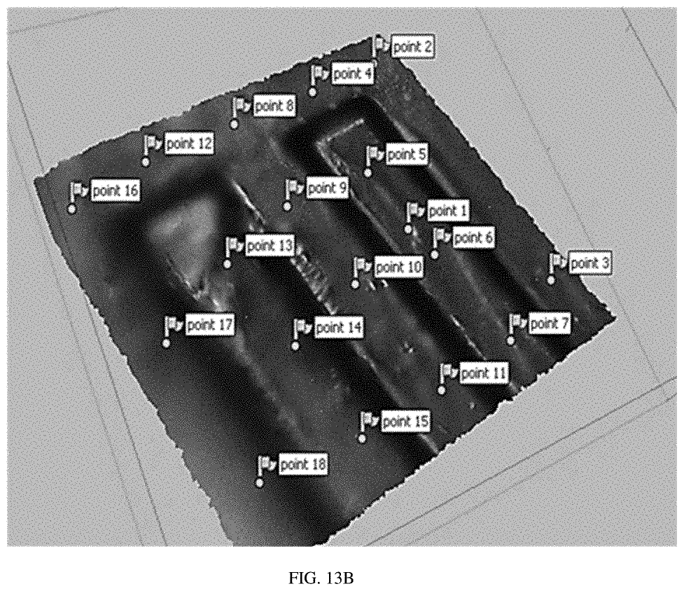

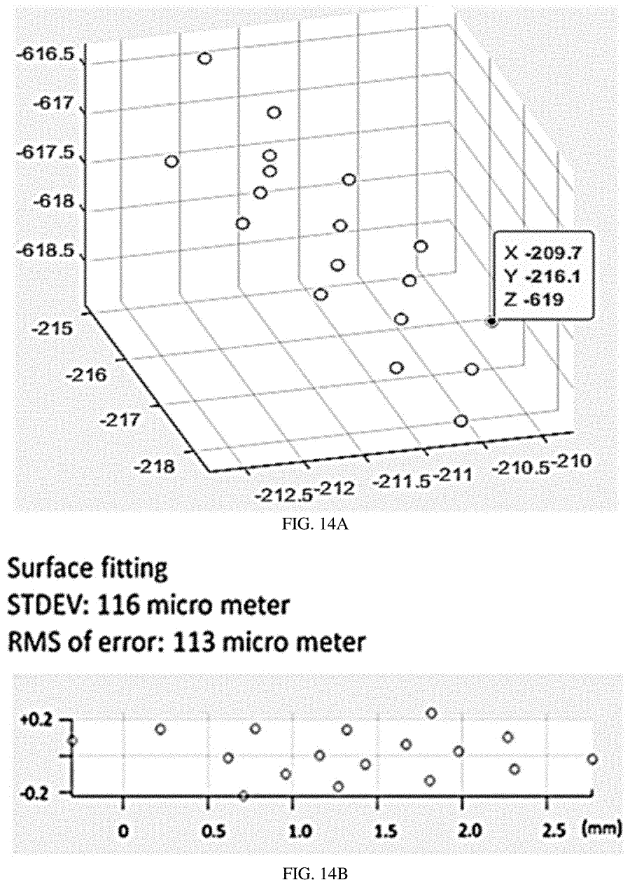

The first model was created by the magnification factor of 30 (see FIG. 13A). The metric used for the 3D modeling accuracy was the flatness of the top surface of the micro-fluidic channel. To that end, 17 point cloud data were captured from the model (FIG. 13B) and processed to create a 3D scatter plot (FIGS. 14A-14B).

In order to measure the flatness, a plane surface fit was used to measure the deviation of each point from the fit surface. FIG. 14A shows the Euclidean distance of each point cloud data to the measured and plotted surface and FIG. 14B shows the surface fitting results. Most of the data points fall within the range of +0.2 to −0.2 mm. The standard deviation and the RMS value were measured to be 116 micrometers and 113 micrometers respectively.

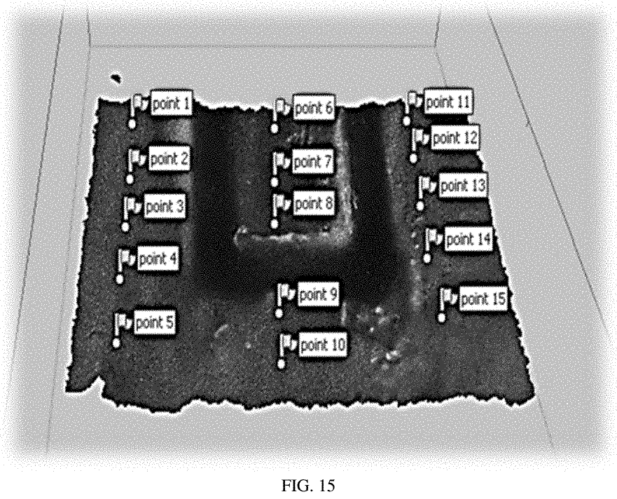

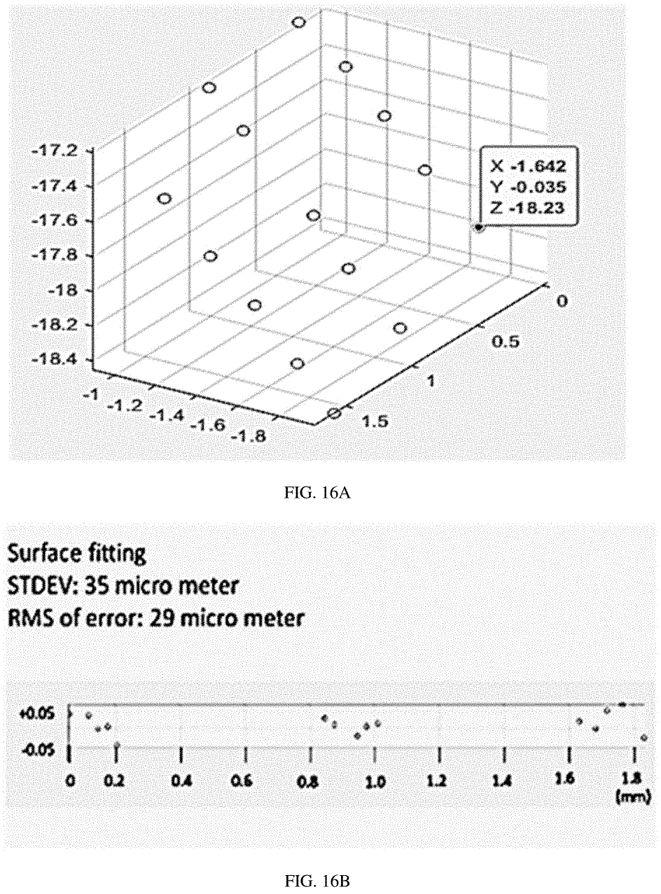

In order to measure the limit of the 3D modeling accuracy of the proposed system, another model of the micro-fluidic channel was created by using the magnification factor of 70 (including the digital zoom factor). FIG. 15 shows that 15 point cloud data were captured for surface flatness accuracy test. FIG. 16A shows the collected data points by scatter 3D representation and FIG. 16B shows the surface fitting results. As shown in FIGS. 16A-16B, all point cloud data were within +/−0.05 mm after surface fitting, representing 35 micrometers of standard deviation and 29 micrometers in RMS value.

### Example 5

### Depth Sensing Accuracy

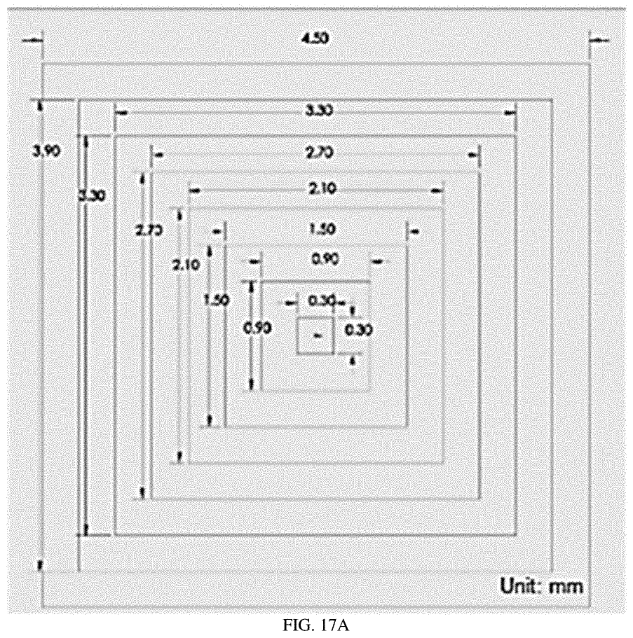

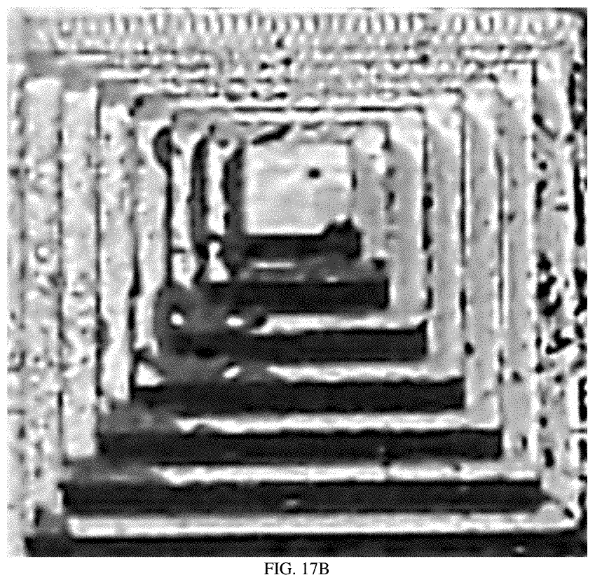

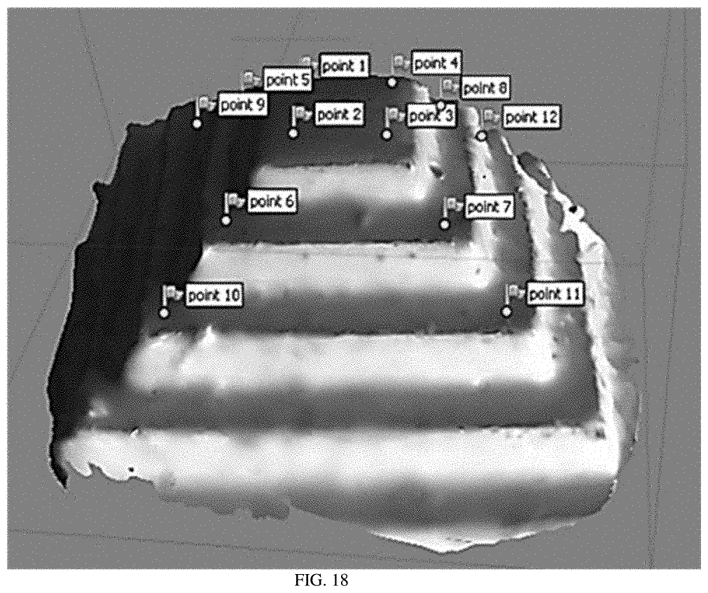

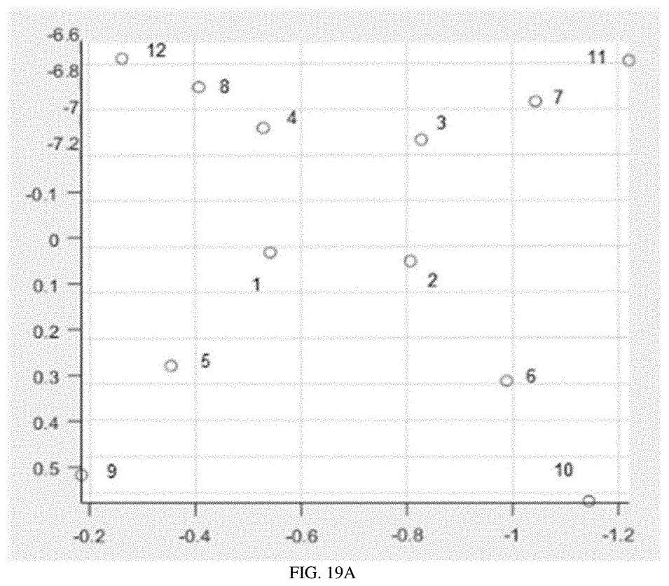

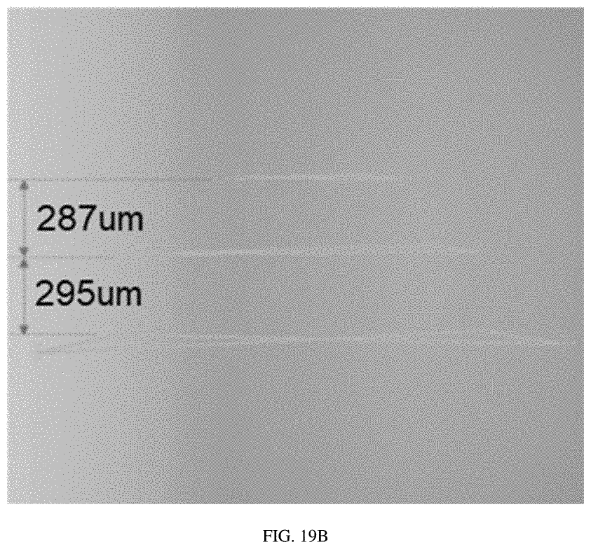

In order to evaluate the depth sensing capability of the exemplary microscale SfM system, a microscale 3D pyramid was designed and carved using the Micro-Milling Machine. As shown in FIGS. 17A-17B, a microscale 3D pyramid comprising a 450 μm² base and a 2,100 μm height (300 μm/step; 7 steps) was created. Using the same magnitude factor (70× zoom), a 3D model of the microscale 3D pyramid was constructed (see FIG. 18). Four point cloud data were sampled from each level to create a plane fitting to each level. As shown in FIG. 19A, a total of 12-point cloud data were depicted in 3D scatter plot along with numbers corresponding to FIG. 18.

In order to measure the height of each step, sampled point cloud data are imported to a CAD tool to evaluate depth measurement accuracy. For precision measurement, the fourth step of the microscale 3D pyramid (450 μm²) was used for original and virtual pyramid calibrations. The Euclidean distance of two point-cloud data sampled at the outside corner of the 4th layer (1.441) was compared to the original design size of 210 μm. As shown in FIG. 19B, using the calibration factor (145.73), the depth of the first two steps from the top were measured to be 287 μm and 295 μm, respectively. Therefore, the error in measurement from the original microscale 3D pyramid dimension was 13 μm for the first step and 5 μm for the second step, demonstrating superior depth measurement capability of the microscale SfM system.

1. A microscale three-dimensional modeling system comprising i) a lighting condition, ii) a camera, iii) a microscope, and iv) a mobile photographic platform.

2. The system of claim 1, wherein the lighting condition comprises absolute lightening, relative lightening, or a combination thereof.

3. The system of claim 1, wherein the lighting condition comprises absolute lightening.

4. The system of claim 1, wherein the lighting condition comprises relative lightening.

5. The system of claim 1, wherein the system further comprises a Surface from Motion (SfM)-based software.

6. The system of claim 1, wherein the camera comprises a focal length that is greater than a depth of measurement.

7. The system of claim 1, wherein the camera comprises a zoom magnification power between 7× and 45×.

8. The system of claim 1, wherein the camera is connected to the microscope.

9. The system of claim 1, wherein the microscope comprises a magnification power between 2× and 45×.

10. The system of claim 1, wherein the mobile photographic platform is configured under the microscope.

11. The system of claim 1, wherein the system further comprises a computer aided design (CAD) component.

12. A method of generating a three-dimensional surface model of an object, said method comprising the step of using the microscale three-dimensional modeling system of claim 1 to provide the three dimensional surface model of the object.

13. The method of claim 12, wherein the method comprises a 3D photo stitching process.

14. The method of claim 13, wherein the 3D photo stitching process comprises an overlap between photos between 60% and 80%.

15. The method of claim 12, wherein the method comprises obtaining one or more photos of the object at a 45° angle around the vertical axis of the object.

16. The method of claim 12, wherein the object is between 1 μm and 1000 μm in size.

17. The method of claim 12, wherein the object is between 100 μm and 1000 μm in size.

18. The method of claim 12, wherein the object is between 500 μm and 1000 μm in size.

19. The method of claim 12, wherein the object is selected from the group consisting of a micro part assembly automation, a biomedical device, a biomedical device fabrication, a biological specimen, a microchemical specimen, and a physical specimen.

20. A method of generating a three-dimensional CAD model of an object, said method comprising the step of using the microscale three-dimensional modeling system of claim 1 to provide a three dimensional surface model of the object, and further comprising performing a CAD operation to provide the three dimensional CAD model of the object.
